(19) United States
(12) Patent Application Publication
(10) Pub. No.: US 2026/0111624 A1
(43) Pub. Date: Apr. 23, 2026

(54) CHECKPOINT-BASED SIMULATION OF HARDWARE DESIGN

(71) Applicant: International Business Machines Corporation, Armonk, NY (US)

(72) Inventors: Divya Kumudprakash Joshi, BANGALORE (IN); Shaun Thomas Uldrikis, POUGHKEEPSIE, NY (US); Eugene Seth Rotter, POUGHKEEPSIE, NY (US); Ajit Shailappa Honnungar, Bangalore (IN)

(21) Appl. No.: 18/922,251

(22) Filed: Oct. 21, 2024

(51) Int. Cl. G06F 30/20

(52) U.S. Cl. CPC G06F 30/20

(57) ABSTRACT

An example operation may include one or more of capturing a state of a data structure of a software design of a hardware device during execution of a first test case via simulation software, pre-loading the data structure of the software design of the hardware device with the captured state to generate a pre-loaded software design of the hardware device, executing a second test case of the pre-loaded software design of the hardware device via execution of the simulation software, and generating test results from the execution of the second test case.

### BACKGROUND

A coded design of a device (e.g., an integrated circuit, etc.) may be written in a hardware design language and may be simulated by a hardware simulator to verify how the device performs. However, it is often difficult to verify all performance scenarios due to the complexity of steps that must be taken to reach certain branches, or the like. As an example, certain functionality/logic can only be tested if a device has previously made a number of decisions and stored the results of those decisions in a data structure such as a branch history table. In many cases, a tester is unaware of these branches and may only reach them by chance. Therefore, it is common for errors in hardware designs to be missed due to untested logic that is difficult to reach through a test case.

### SUMMARY

One example embodiment provides an apparatus that may include a memory and at least one processor communicatively coupled to the memory, where the at least one processor may perform one or more of capture a state of a data structure of a software design of a hardware device during execution of a first test case via simulation software, pre-load the data structure of the software design of the hardware device with the captured state to generate a pre-loaded software design of the hardware device, execute a second test case of the pre-loaded software design of the hardware device via execution of the simulation software, and generate test results from the execution of the second test case.

Another example embodiment provides a method that may include one or more of capturing a state of a data structure of a software design of a hardware device during execution of a first test case via simulation software, pre-loading the data structure of the software design of the hardware device with the captured state to generate a pre-loaded software design of the hardware device, executing a second test case of the pre-loaded software design of the hardware device via execution of the simulation software, and generating test results from the execution of the second test case.

A further example embodiment provides a computer-readable hardware storage medium that includes instructions which when executed by a processor may cause the processor to perform one or more of capturing a state of a data structure of a software design of a hardware device during execution of a first test case via simulation software, pre-loading the data structure of the software design of the hardware device with the captured state to generate a pre-loaded software design of the hardware device, executing a second test case of the pre-loaded software design of the hardware device via execution of the simulation software, and generating test results from the execution of the second test case.

### BRIEF DESCRIPTION OF THE DRAWINGS

FIG. 1 is a diagram illustrating a computing environment according to an embodiment of the instant solution.

FIG. 2A is a diagram illustrating a process of capturing a checkpoint of a state of a data structure during execution of a hardware simulation according to the examples and features of the instant solution.

FIG. 2B is a diagram illustrating a process of pre-loading a checkpointed state to a data structure of a design and executing a hardware simulation with the pre-loaded state according to the examples and features of the instant solution.

FIG. 3 is a diagram illustrating a user interface for pre-loading a checkpointed state according to the examples and features of the instant solution.

FIG. 4 is a diagram illustrating a process of filling a data structure according to the examples and features of the instant solution.

FIG. 5A is a diagram illustrating a flow diagram, according to example embodiments.

FIG. 5B is a diagram illustrating a flow diagram, according to example embodiments.

### DETAILED DESCRIPTION

It is to be understood that although this disclosure includes a detailed description of cloud computing, implementation of the teachings recited herein is not limited to a cloud computing environment. Rather, embodiments of the instant solution are capable of being implemented in conjunction with any other type of computing environment now known or later developed.

Hardware simulators are used to test and validate hardware designs, which are coded in software form, for example, using a hardware design language. Hardware simulations can be used to detect issues, fix the issues, and thus improve the quality and reliability of a design before the design is fabricated as a physical device and the software is embedded in the physical device, such as an integrated circuit. A design may be composed of numerous modules (e.g., hundreds, thousands, etc.) that are interconnected to make a system properly operate. It can be difficult to verify the design functions in an expected manner because it can be difficult to test each module and the system as a whole. A single incorrect bit can cause the system to perform improperly or not function at all, with little or no observability of what occurred. A simulator simulates how the design will perform using tests/test cases, which can identify design flaws, bugs, and the like early in the hardware design process.

Test cases are typically designed to test a specific function, module, etc., of the design against requirements of the design. For example, if a device is required to perform a touch identification, testing through a simulator can determine whether such touch identification will work properly prior to the design being integrated into a physical device. Thus, the simulator enables the designer/tester to test real-life scenarios prior to building the physical design.

For complex designs, the testing and verification may need to cover a large state space because of different combinations of decisions/branches that can be made, different types of scenarios, and the like. Reaching these harder-to-find locations within the design can be very difficult, especially for test cases that are designed to only test a specific function of the design. For example, branch prediction logic can be particularly difficult to test because it often requires long-running tests to test the whole state space, which is made more difficult by an empty state/default state of data structures within the design. Data structures, as described herein, may include registers, arrays, queues, caches, linked lists, hash tables, branch history tables, trees, heaps, graphs, stacks, and the like. In order for certain functionality to be fully tested, a data structure may require a specific history/state stored therein, which can be difficult to identify resulting in parts of the state space being untested.

The example embodiments are directed to a system that is configured to “pre-load” a data structure with a previously captured state of the data structure (referred to herein as a checkpoint). The previously captured state of the data structure may include state data of the design (e.g., branch predictions made, etc.) during a previous test case performed/simulated on the design. By pre-loading the data structure with the previously captured state, specific parts, functions, logic, etc., within the design can be tested immediately. Thus, the pre-loading action can reduce the overall time necessary for a test, reduce the number of tests, improve the accuracy of the state space that is covered by the tests, and the like.

In some embodiments, the checkpoint is configured to be captured during a previous run of the same test case. Therefore, a test case may be executed initially with the data structure(s) empty or otherwise in the default state. When an interesting event, state, etc. occurs during the execution of the test case, a checkpoint of the state of the data structure(s) and its content may be captured by the system. In some embodiments, the checkpoints are configured to be captured at predetermined intervals (e.g., after each prediction, after a predetermined number of predictions, etc.). As another example, a user can initiate an action, via a graphical user interface (GUI) of the system, for example, which triggers the capture of the checkpoint.

In some embodiments, the checkpointed state of the data structure(s) is configured to be limited in scope resulting in a partial checkpoint. For example, some data stored within the data structure may be used while some may be discarded or otherwise reset, causing a limited scope. Thus, the system can identify interesting states during the execution of the test case which is suspected to lead to currently missed/unreachable events. Furthermore, the system is configured to record/capture a model state based on a checkpoint, limit the scope of the captured model state (e.g., extracting a reset file, etc.) from the checkpoint, and rerun the original test cases with the data structure pre-loaded with the extracted checkpoint.

Some of the benefits of the system described herein include capturing a state of a design at interesting points during testing, rerunning the same tests on the same stimulus (test case inputs, etc.) with the captured state stored within the data structure(s) at the beginning of the test cases, pre-loading data structures that do not have a pre-loader, and the like. The system can save computing resources and find harder-to-reach bugs and unexplored state space.

The system, which executes the checkpointing and pre-loading described herein, is configured to be implemented within software such as a software application (e.g., a hardware simulator, etc.) a software service, or the like, which may be hosted by a host platform such as a cloud platform, a web server, a database, or the like.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or data center).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure, including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure, including networks, servers, operating systems, or storage, but has control over the deployed applications and possibly the application hosting environment configurations.

Infrastructure as a Service (IaaS): the capability provided to the consumer is to provision processing, storage, networks, and other fundamental computing resources where the consumer can deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community with shared concerns (e.g., mission, security requirements, policy, and compliance considerations). It may be managed by organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service-oriented with a focus on statelessness, low coupling, modularity, and semantic interoperability. At the heart of cloud computing is an infrastructure that includes a network of interconnected nodes.

The instant features, structures, or characteristics as described throughout this specification may be combined or removed in any suitable manner in one or more embodiments. For example, the usage of the phrases “example embodiments,” “some embodiments,” or other similar language, throughout this specification refers to the fact that a particular feature, structure, or characteristic described in connection with the embodiment may be included in at least one embodiment. Thus, appearances of the phrases “example embodiments,” “in some embodiments,” “in other embodiments,” or other similar language, throughout this specification do not necessarily all refer to the same group of embodiments, and the described features, structures, or characteristics may be combined or removed in any suitable manner in one or more embodiments. Further, in the diagrams, any connection between elements can permit one-way and/or two-way communication even if the depicted connection is a one-way or two-way arrow. Also, any device depicted in the drawings can be a different device. For example, if a mobile device is shown sending information, a wired device could also be used to send the information.

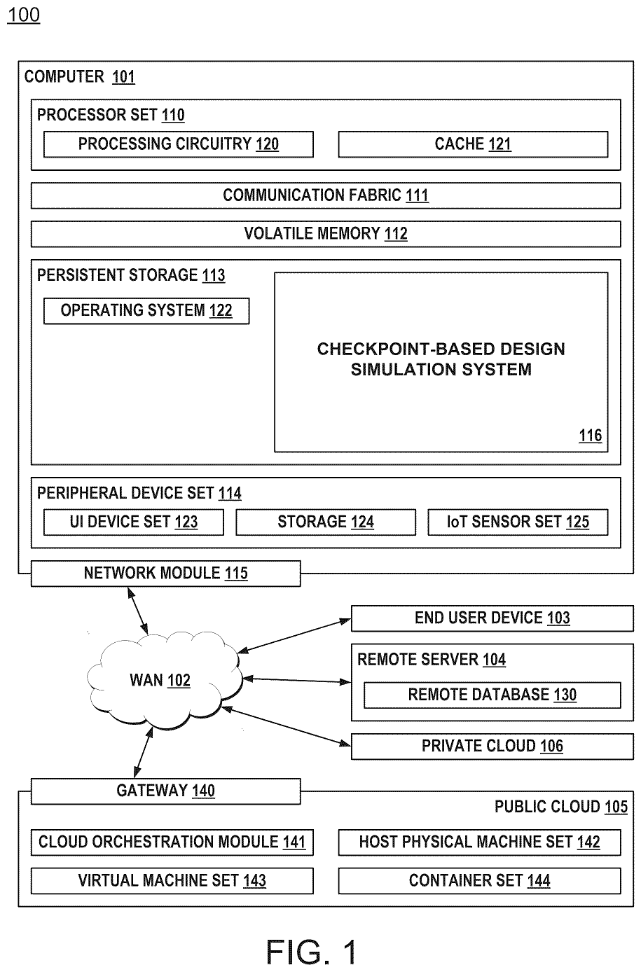

FIG. 1 illustrates a computing environment 100 according to an embodiment of the instant solution. Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again, depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Referring to FIG. 1, computing environment 100 contains an example of an environment for executing at least some of the computer code involved in performing the inventive methods, such as checkpoint-based design simulation system 116. In addition to block 116, computing environment 100 includes, for example, computer 101, wide area network (WAN) 102, end-user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 116, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smartphone, smartwatch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, the performance of a computer-implemented method may be distributed among multiple computers and/or between multiple locations. On the other hand, in this presentation of the computing environment 100, a detailed discussion is focused on a single computer, specifically the computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is a memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off-chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 116 in persistent storage 113.

COMMUNICATION FABRIC 111 is the signal conduction path that allows the various components of computer 101 to communicate with each other. Typically, this fabric comprises switches and electrically conductive paths, such as the switches and electrically conductive paths that make up buses, bridges, physical input/output ports, and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read-only memory (ROM), but typically at least a portion of the persistent storage allows writing of data, deletion of data, and re-writing of data. Some familiar forms of persistent storage include magnetic disks and solid-state storage devices. Operating system 122 may take several forms, such as various known proprietary operating systems or open-source Portable Operating System Interface type operating systems that employ a kernel. The code included in block 116 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth® connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smartwatches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer, and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi® signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data now known or to be developed in the future. In some embodiments, the WAN may be replaced and/or supplemented by local area networks (LANs) designed to communicate data between devices located in a local area, such as a Wi-Fi® network. The WAN and/or LANs typically include computer hardware such as copper transmission cables, optical transmission fibers, wireless transmission, routers, firewalls, switches, gateway computers, and edge servers.

END USER DEVICE (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer, and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, this data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanations of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as communicating with WAN 102, in other embodiments, a private cloud may be disconnected from the internet entirely and only accessible through a local/private network. A hybrid cloud is a composition of multiple clouds of different types (for example, private, community, or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both parts of a larger hybrid cloud.

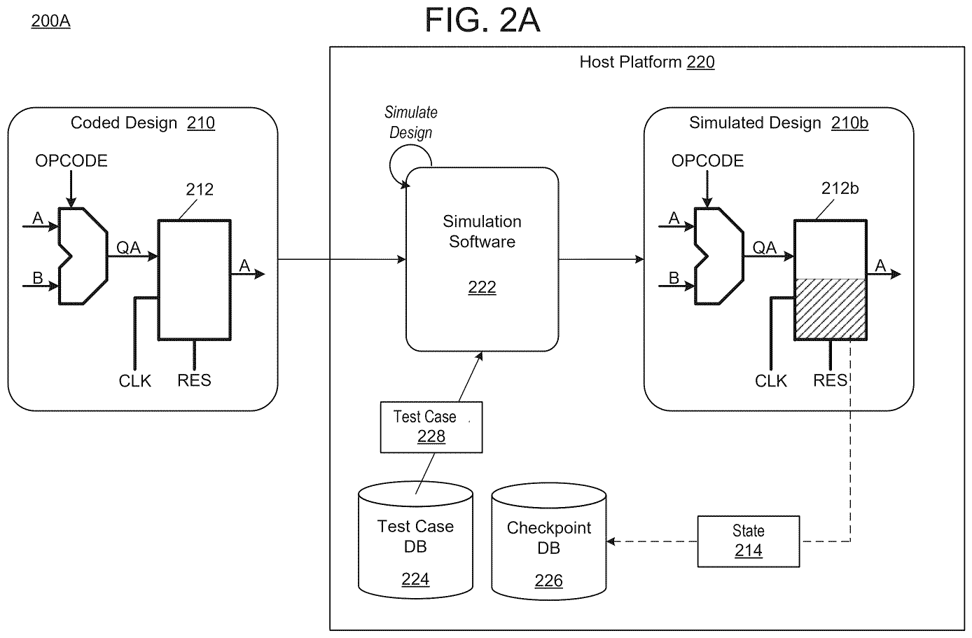

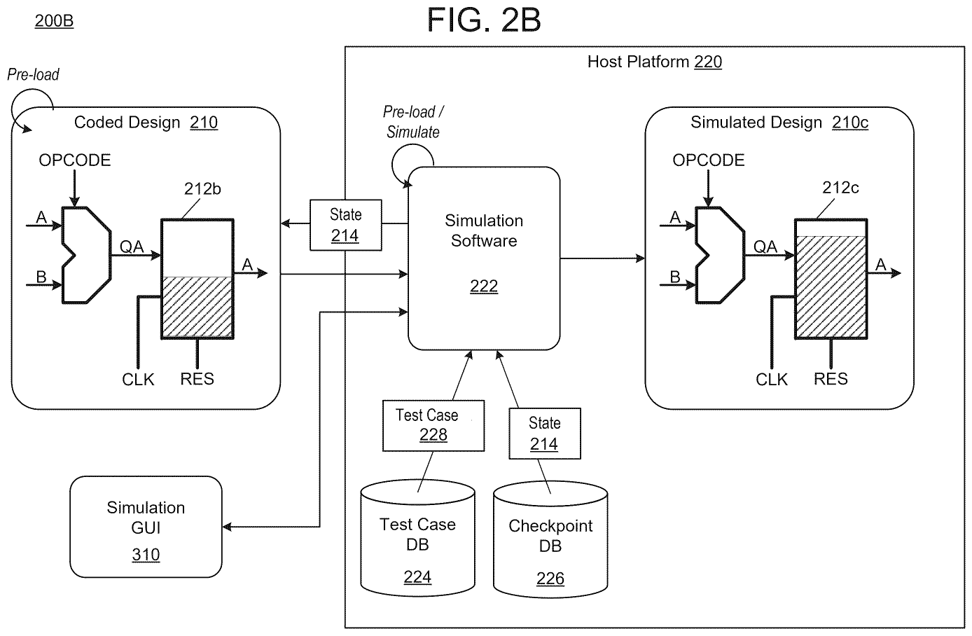

FIG. 2A illustrates a process 200A of capturing a checkpoint of a state 214 of a data structure 212 during execution of a hardware simulation according to examples and features of the instant solution. Referring to FIG. 2A, a hardware design such as a circuit or other physical device may be coded through a programming language such as a hardware design language, resulting in a coded design 210. The coded design may include physical elements in coded form, including data structures such as data structure 212. The data structure 212 may store data based on the simulation that is being performed, referred to herein as a state. The coded design 210 may be input into simulation software 222, such as a hardware simulator, which is capable of running tests on the coded design 210. In this example, the simulation software 222 is hosted by a host platform 220, such as a cloud platform, a web server, a combination of systems, and the like.

Although not shown in FIG. 2A, the coded design 210 may be input to the simulation software 222 by a user device that is connected to the host platform 220 over a computer network. For example, the simulation software 222 may be hosted at a web address, uniform resource locator, IP address, or the like. Further, the simulation software 222 may execute a test case 228 on the coded design 210 and may retrieve the test case 228 from a test case database 224 of the simulation software 222.

The test case 228 may include a starting state for one or more elements, data structures, or the like. The test case 228 may also include input stimulus, expected results, and the like. The simulation software 222 may execute the test case 228 while simulating the coded design 210 to generate a simulated design 210b. The simulation process may cause the data structure 212 to store data therein, resulting in an updated data structure 212b with an updated state in comparison to the data structure 212 in the coded design 210.

According to various embodiments, the simulation software 222 may capture a checkpoint of the state 214 of the updated data structure 212b and record the checkpoint of the state 214 within a checkpoint database 226. For example, the simulation software 222 may iteratively capture checkpoints at different points in times, events, etc., within the simulation performed by the simulation software 222. As an example, each time a branch prediction occurs, the simulation software 222 may capture a checkpoint of the state of the data structure. As another example, the simulation software 222 may capture a checkpoint in response to a user input via a GUI of the simulation software 222. The checkpointed state of the data structure may be used to pre-load the data structure during a subsequent test case, such as the same test case or a different test case.

FIG. 2B illustrates a process 200B of pre-loading the state 214 to a data structure of the coded design and executing a hardware simulation with the pre-loaded state according to examples and features of the instant solution. Referring to FIG. 2B, the test case 228 may be re-executed on the coded design 210. However, in this example, rather than the data structure 212 being empty or having no state at all, the data structure may be pre-loaded with the state 214 captured during the process 200A of FIG. 2A to return the data structure 212 to the updated data structure 212b. As a result, the test case 228 may be re-executed on the coded design 210, with the updated data structure 212b, rather than the original (empty) data structure 212.

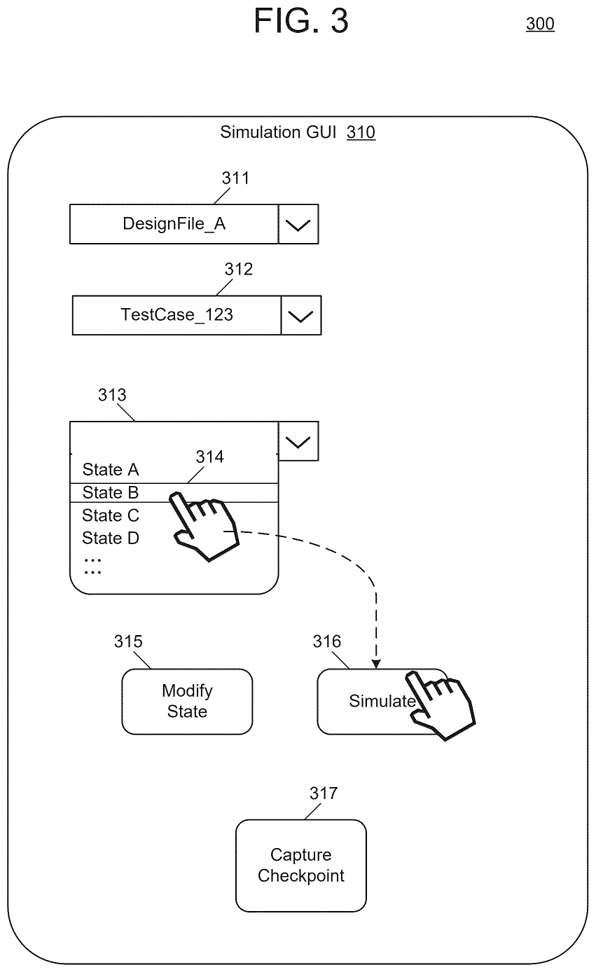

According to various embodiments, a user may request the coded design 210 be preloaded based on commands that are entered via a GUI 310 of the simulation software 222. A further example of the simulation GUI 310 is shown and described in FIG. 3. Referring again to FIG. 2B, the simulation software 222 may receive the instructions from the simulation GUI 310 and may retrieve the checkpointed state (the state 214) of the data structure 212 from the checkpoint database 226 and may pre-load the data structure 212 within the coded design 210 to generate a preloaded data structure (the updated data structure 212b). Furthermore, the simulation software 222 may retrieve the test case 228 from the test case database 224 and execute the test case 228 while simulating the coded design 210 with the updated data structure 212b.

The result of the simulation is a further simulated design 210c, and the data structure may include a further updated data structure 212c. By pre-loading the data structure 212 with the checkpointed state, the simulation can reach different/more difficult-to-reach state spaces of the coded design. For example, some features can only be tested after numerous previous branch predictions have been made. In this case, by pre-loading the data structure 212 (such as a branch history table, etc.) with a previous state, the testing process can reach a different state space than the first run of the test case 228 during the process 200A of FIG. 2A. Here, the data structure may be pre-loaded with traffic (predictions, stored content, etc.) that occurs during the prior simulation of the test case 228. Therefore, higher value can be obtained from the same test case by running it again with a different state included in the data structure.

Although FIGS. 2A-2B provide a coded design with only one data structure, it should be appreciated that the coded design may include multiple data structures, and each or some of the data structures may be pre-loaded, thereby creating numerous possibilities for pre-loading. It should also be appreciated that a user may limit the scope of the previously captured state by resetting certain parts, deleting certain parts, or the like, thereby focusing the test on a specific function, operand, bit, etc.

FIG. 3 illustrates a view 300 of the simulation GUI 310 of the simulation software 222 according to the examples and features of the instant solution. Referring to FIG. 3, a user may input commands to the simulation GUI 310 to cause the simulation software to capture checkpoints of a state of a data structure(s), modify the state data of a checkpoint, pre-load a data structure with a previous state, and the like. For example, the simulation GUI 310 may include input elements such as sliders, buttons, input fields, menus, checkboxes, and the like, which can be manipulated by a user touching a screen, moving a cursor, or the like.

For example, the simulation GUI 310 may include a drop-down menu 311 which enables a user to select a coded design for purposes of simulation. The simulation GUI 310 also may include a drop-down menu 312, which enables the selection of a test case for execution on the coded design selected via the drop-down menu 311. In addition, the simulation GUI 310 may include a drop-down menu 313 for selecting a previously captured state 314 (e.g., a checkpoint) of a data structure and pre-loading a data structure of the selected coded design with the previously captured state.

The simulation GUI 310 also may include a GUI element, such as a modification button 315, which a user can select to modify/limit a scope of a previously captured state (checkpoint). The modification button 315 may open another page which enables the user to select specific elements of the previously captured state to be removed and/or kept. The simulation GUI 310 also may include a GUI element, such as a simulation button 316, which, when pressed, will execute a simulation of the coded design and run the test case on the simulation of the coded design. The simulation GUI 310 also may include a GUI element, such as a capture checkpoint button 317, which can be pressed during a simulation to capture a state of a data structure or structures during the simulation and record the states.

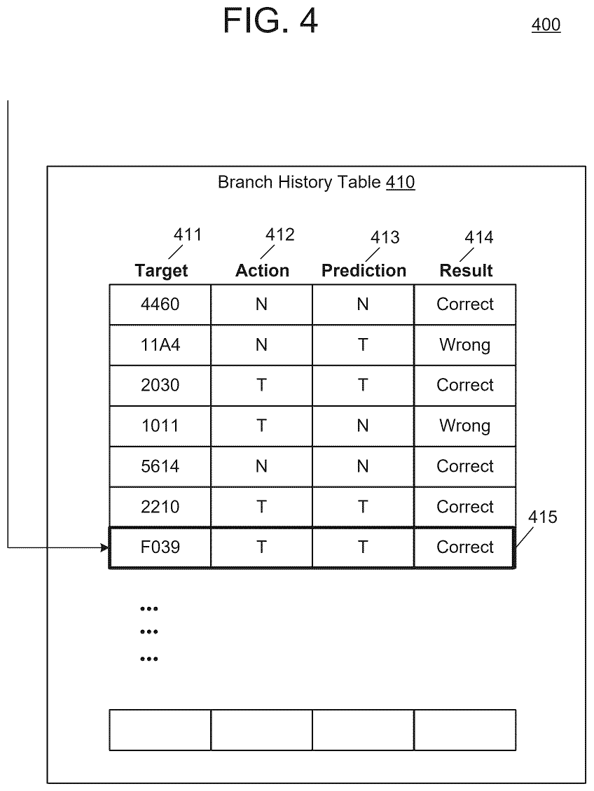

FIG. 4 illustrates a process 400 of filling a data structure 410 according to the examples and features of the instant solution. As an example, the data structure 410 may be a branch history table that stores branch prediction results made by a design during simulation. Although not shown in FIG. 4, another data structure may be a branch table buffer. In some embodiments, multiple data structures may be checkpointed including a combination of the branch history table and the branch table buffer, enabling even more combinations of state that can be preserved and used to finely test the coded design.

In the example of FIG. 4, the data structure 410 (branch history table) may include a plurality of columns of data values, including a column 411 storing a target address of a branch instruction, a column 412 representing the action taken during the simulation, a column 413 representing the predicted action that would be taken, a column 414 including an indicator of whether the prediction is correct, and the like. In this example, each time a new prediction is made, the data structure 410 receives a new entry 415 of data, including values for each of the columns.

According to various embodiments, the content stored within the data structure 410 may be captured and stored as a checkpointed state of the data structure 410. Accordingly, when pre-loading the data structure, the content shown in FIG. 4 may be pre-loaded into the data structure 410 prior to a simulation of a test thereby testing the data structure 410 in a specific state.

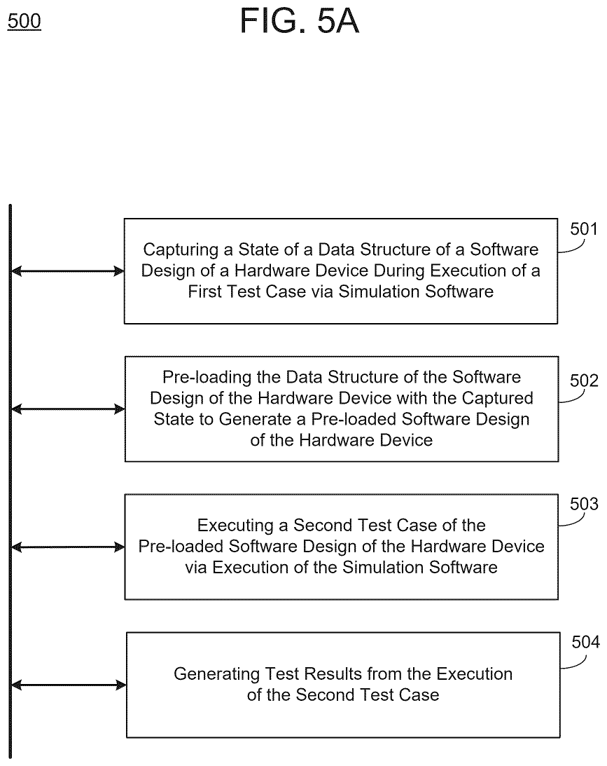

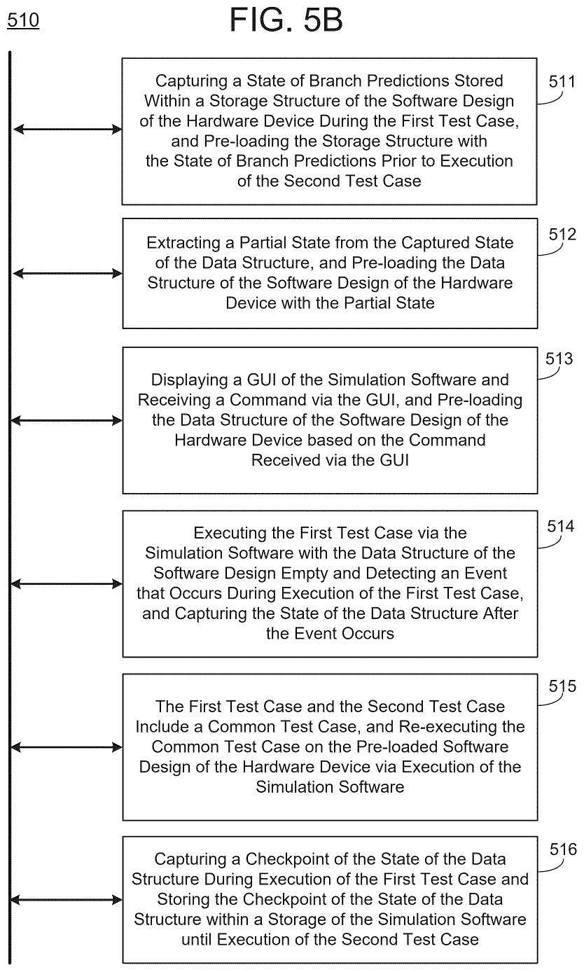

FIG. 5A illustrates a flow diagram of a method 500, according to example embodiments. Referring to FIG. 5A, in 501, the method may include capturing a state of a data structure of a software design of a hardware device during execution of a first test case via simulation software. In 502, the method may include pre-loading the data structure of the software design of the hardware device with the captured state to generate a pre-loaded software design of the hardware device. In 503, the method may include executing a second test case of the pre-loaded software design of the hardware device via execution of the simulation software. In 504, the method may include generating test results from the execution of the second test case.

FIG. 5B illustrates a flow diagram of a method 510, according to example embodiments. Referring to FIG. 5B, in 511, the method may include capturing a state of branch predictions stored within a storage structure of the software design of the hardware device during the first test case and pre-loading the storage structure with the state of branch predictions prior to execution of the second test case. In 512, the method may include extracting a partial state from the captured state of the data structure, wherein the pre-loading comprises pre-loading the data structure of the software design of the hardware device with the partial state. In 513, the method may include displaying a GUI of the simulation software and receiving a command via the GUI, wherein the pre-loading comprises pre-loading the data structure of the software design of the hardware device based on the command received via the GUI.

In 514, the method may include executing the first test case via the simulation software with the data structure of the software design empty and detecting an event that occurs during execution of the first test case, wherein the capturing comprises capturing the state of the data structure after the event occurs. In 515, the first test case and the second test case include a common test case, and executing the second test case may include re-executing the common test case on the pre-loaded software design of the hardware device via execution of the simulation software. In 516, the method may include capturing a checkpoint of the state of the data structure during the execution of the first test case and storing the checkpoint of the state of the data structure within a storage of the simulation software until the execution of the second test case.

The above embodiments may be implemented in hardware, in a computer program executed by a processor, in firmware, or in a combination of the above. A computer program may be embodied on a computer readable medium, such as a storage medium. For example, a computer program may reside in random access memory (“RAM”), flash memory, read-only memory (“ROM”), erasable programmable read-only memory (“EPROM”), electrically erasable programmable read-only memory (“EEPROM”), registers, hard disk, a removable disk, a compact disk read-only memory (“CD-ROM”), or any other form of storage medium known in the art.

An exemplary storage medium may be coupled to the processor such that the processor may read information from, and write information to, the storage medium. In the alternative, the storage medium may be integral to the processor. The processor and the storage medium may reside in an application-specific integrated circuit (“ASIC”). In the alternative, the processor and the storage medium may reside as discrete components.

What is claimed is:

1. An apparatus comprising:
a memory; and
at least one processor coupled to the memory, the at least one processor configured to:
capture a state of a data structure of a software design of a hardware device during execution of a first test case via simulation software;
pre-load the data structure of the software design of the hardware device with the captured state to generate a pre-loaded software design of the hardware device;
execute a second test case of the pre-loaded software design of the hardware device via execution of the simulation software; and
generate test results from the execution of the second test case.

2. The apparatus of claim 1, wherein the at least one processor is configured to capture a state of branch predictions stored within a storage structure of the software design of the hardware device during the first test case, and pre-load the storage structure with the state of branch predictions prior to execution of the second test case.

3. The apparatus of claim 1, wherein the at least one processor is further configured to extract a partial state from the captured state of the data structure and pre-load the data structure of the software design of the hardware device with the partial state.

4. The apparatus of claim 1, wherein the at least one processor is further configured to display a graphical user interface (GUI) of the simulation software, receive a command via the GUI, and pre-load the data structure of the software design of the hardware device based on the command received via the GUI.

5. The apparatus of claim 1, wherein the at least one processor is further configured to execute the first test case via the simulation software with the data structure of the software design empty, and capture the state of the data structure after an event occurs during execution of the first test case.

6. The apparatus of claim 1, wherein the first test case and the second test case include a common test case, and the at least one processor is configured to re-execute the common test case of the pre-loaded software design of the hardware device via execution of the simulation software.

7. The apparatus of claim 1, wherein the at least one processor is configured to capture a checkpoint of the state of the data structure during execution of the first test case and store the checkpoint of the state of the data structure within a storage of the simulation software until execution of the second test case.

8. A method comprising:
capturing a state of a data structure of a software design of a hardware device during execution of a first test case via simulation software;
pre-loading the data structure of the software design of the hardware device with the captured state to generate a pre-loaded software design of the hardware device;
executing a second test case of the pre-loaded software design of the hardware device via execution of the simulation software; and
generating test results from the execution of the second test case.

9. The method of claim 8, wherein the capturing comprises capturing a state of branch predictions stored within a storage structure of the software design of the hardware device during the first test case, and the pre-loading comprises pre-loading the storage structure with the state of branch predictions prior to execution of the second test case.

10. The method of claim 8, further comprising extracting a partial state from the captured state of the data structure, wherein the pre-loading comprises pre-loading the data structure of the software design of the hardware device with the partial state.

11. The method of claim 8, further comprising displaying a graphical user interface (GUI) of the simulation software and receiving a command via the GUI, wherein the pre-loading comprises pre-loading the data structure of the software design of the hardware device based on the command received via the GUI.

12. The method of claim 8, further comprising executing the first test case via the simulation software with the data structure of the software design empty and detecting an event that occurs during execution of the first test case, wherein the capturing comprises capturing the state of the data structure after the event occurs.

13. The method of claim 8, wherein the first test case and the second test case include a common test case, and the executing the second test case comprises re-executing the common test case on the pre-loaded software design of the hardware device via execution of the simulation software.

14. The method of claim 8, wherein the capturing comprises capturing a checkpoint of the state of the data structure during execution of the first test case and storing the checkpoint of the state of the data structure within a storage of the simulation software until execution of the second test case.

15. A computer-readable hardware storage medium comprising instructions which when executed by a processor cause the processor to perform:
capturing a state of a data structure of a software design of a hardware device during execution of a first test case via simulation software;
pre-loading the data structure of the software design of the hardware device with the captured state to generate a pre-loaded software design of the hardware device;
executing a second test case of the pre-loaded software design of the hardware device via execution of the simulation software; and
generating test results from the execution of the second test case.

16. The computer-readable hardware storage medium of claim 15, wherein the capturing comprises capturing a state of branch predictions stored within a storage structure of the software design of the hardware device during the first test case, and the pre-loading comprises pre-loading the storage structure with the state of branch predictions prior to execution of the second test case.

17. The computer-readable hardware storage medium of claim 15, wherein the processor is further configured to perform extracting a partial state from the captured state of the data structure, wherein the pre-loading comprises pre-loading the data structure of the software design of the hardware device with the partial state.

18. The computer-readable hardware storage medium of claim 15, wherein the processor is further configured to perform displaying a graphical user interface (GUI) of the simulation software and receiving a command via the GUI, wherein the pre-loading comprises pre-loading the data structure of the software design of the hardware device based on the command received via the GUI.

19. The computer-readable hardware storage medium of claim 15, wherein the processor is further configured to perform executing the first test case via the simulation software with the data structure of the software design empty and detecting an event that occurs during execution of the first test case, wherein the capturing comprises capturing the state of the data structure after the event occurs.

20. The computer-readable hardware storage medium of claim 15, wherein the first test case and the second test case include a common test case, and the executing the second test case comprises re-executing the common test case on the pre-loaded software design of the hardware device via execution of the simulation software.
